(19) United States
(12) Patent Application Publication
(10) Pub. No.: US 2010/0079972 A1
(43) Pub. Date: Apr. 1, 2010

(54) SHIELD CAN

(75) Inventors: YONG CHEN, Shenzhen City (CN); LI-ZHI XIONG, Shenzhen City (CN); LIANG QIU, Shenzhen City (CN); XIANG-BO ZENG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (Hong Kong) Limited, Kowloon (HK)

(21) Appl. No.: 12/561,361

(22) Filed: Sep. 17, 2009

(30) Foreign Application Priority Data
Sep. 26, 2008 (CN) 200810304694.2

(51) Int. Cl. H05K 9/00

(52) U.S. Cl. 361/818

(57) ABSTRACT

A shield can includes a frame and an enclosure, the frame includes a top wall and sidewalls, the sidewalls defines a plurality of latching holes extending through the top wall, and the top wall forms extending portion corresponding to the latching hole. The enclosure includes a main plate and walls, the wall forms depression portions corresponding to the latching holes, the depression portion defines a cutout extending through the main plate. The enclosure is attached to the frame, the depression portions latch into the latching holes and the extending portions latch into the cutouts accordingly.

### CROSS-REFERENCE TO RELATED APPLICATIONS

This application is related to a co-pending U.S. Patent Application (Attorney Docket No. US23593), entitled “SHIELD CAN AND METHOD FOR FABRICATING THE SAME”, by Qi Wang. Such applications have the same assignee as the present application. The above-identified applications are incorporated herein by reference.

### BACKGROUND

1. Technical Field

The present disclosure relates to a shield can for portable electronic devices and a method for fabricating the same.

2. Description of related art

Many electronic components in electronic devices, such as capacitors, are protected by shield cans from external/internal electromagnetic interferences (EMI). A typical shield can is a metallic enclosure locked to a metallic frame. For example, FIG. 3 shows a shield can 50 including a frame 52 and a punched enclosure 54. The frame 52 has two apertures 522 through the top wall and a plurality of latching holes 524 through the peripheral wall. The enclosure 54 has a shielding panel 541 and a plurality of pieces 542 perpendicularly extending from the peripheral edge of the shielding panel 541. Each of the pieces 542 has a corresponding latching protrusion 5422 for securely engaging into a corresponding latching hole 524 to lock the enclosure 54 to the frame 52. Meanwhile, the shielding panel 541 covers the apertures 522 of the frame 52.

However, the latching holes 524 cannot be defined very close to the top wall of the frame 52 for maintaining a secure latching with the latching protrusion 5422. Thus, the configuration of the latching holes 524 makes it difficult to reduce the height and size of the shield can 50.

Therefore, there is room for improvement within the art.

### BRIEF DESCRIPTION OF THE DRAWINGS

Many aspects of the disclosed shield can be better understood with reference to the following drawings. The components in the drawings are not necessarily drawn to scale, the emphasis instead being placed upon clearly illustrating the principles of the exemplary shield can. Moreover, in the drawings, like reference numerals designate corresponding parts throughout the several views.

FIG. 1 is an exploded, schematic view of the shield can according to an exemplary embodiment.

FIG. 2 is an assembled, schematic view of the shield can shown in FIG. 1.

FIG. 3 is an exploded, schematic view of a typical shield can.

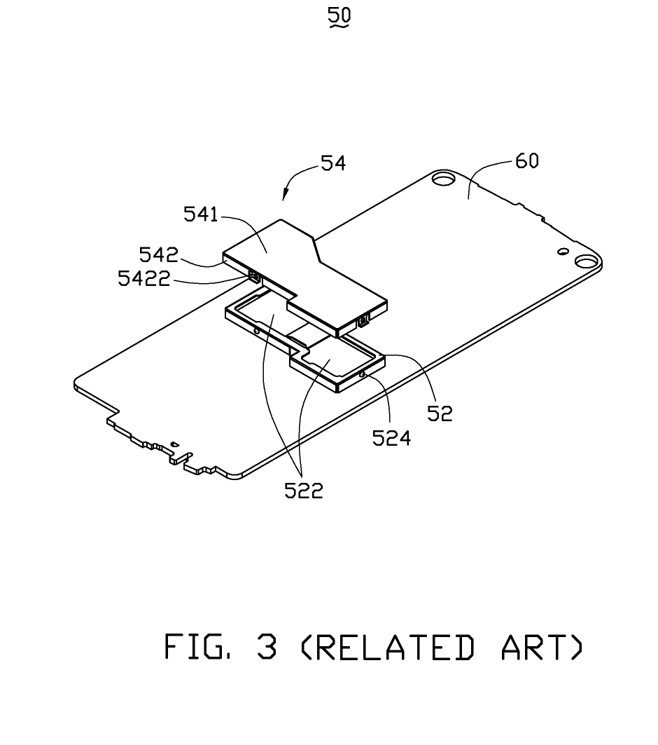

### DETAILED DESCRIPTION OF THE EMBODIMENT

The disclosed shield can is suitable for electronic devices, such as mobile phones, personal digital assistants (PDAs), etc.

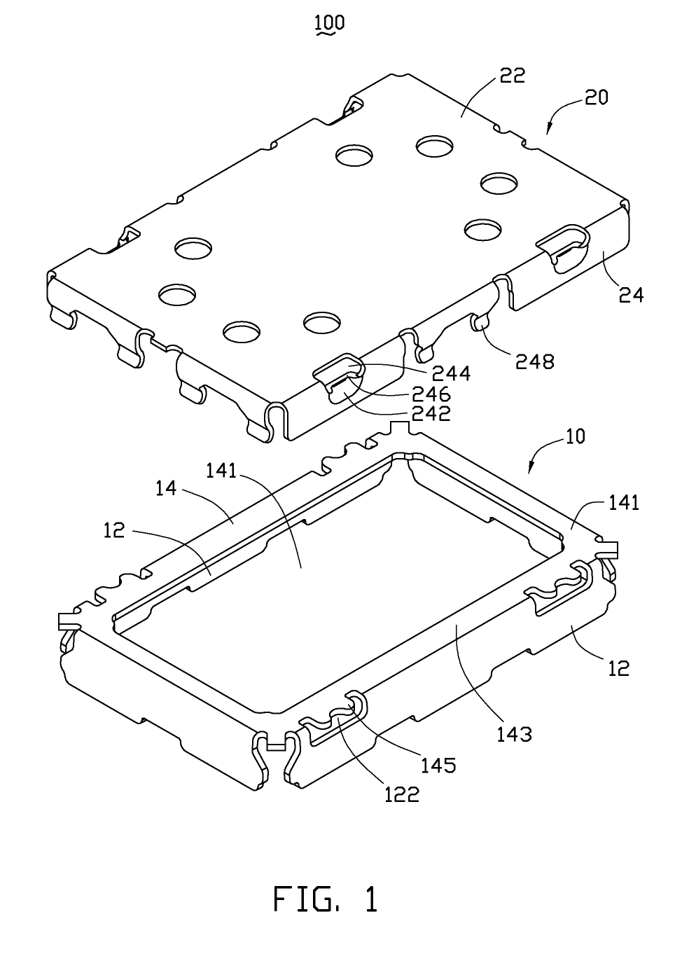

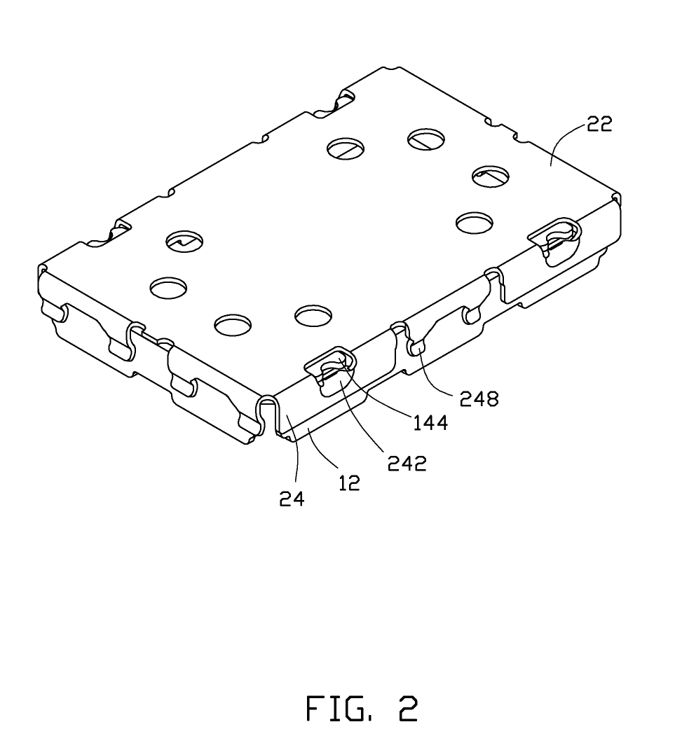

Referring to FIGS. 1 and 2, a shield can 100 according to an exemplary embodiment includes a frame 10 and an enclosure 20 covering the frame 10.

The frame 10 includes a top wall 14 and two opposite sidewalls 12 extending downwardly from a perimeter flange of the top wall 14. The top wall 14 defines a hole 141 which is enclosed by a peripheral flange 143. Each sidewall 12 defines two latching holes 122 extending through the sidewalls 12 and adjacent the top wall 14/flange 143. Accordingly, an extending portion 145 of flange 143 extends above each latching hole 122. The extending portion 145 can be wave-shaped to facilitate an assembly of the frame 10 and the enclosure 20.

The enclosure 20 includes a main plate 22 and two walls 24 extending downwardly from the periphery of the main plate 22. The main plate 22 covers the top wall 14 and shields the hole 141. The wall 24 has two depression portions 242 recessed from the outer surface of the wall 24 and protruding from internal surface correspondingly, and adjacent to the main plate 22. The depression portions 242 correspond in position to the latching holes 122 and are configured for latching into the latching holes 122. Each depression portion 242 defines a through cutout 244 extending through the main plate 22, and thus a resisting surface 246 is formed on the depression portion 242. The cutout 244 is configured for receiving the extending portion 145, and the resisting surface 246 resists the extending portions 145. The wall 24 has a plurality of holding pieces 248 for resisting the sidewalls 12 of the frame 10. Each holding piece 248 has a tail end towards the inside of the enclosure 20.

During assembly of the shield can 100, the enclosure 20 is pressed towards to cover the frame 10. The depression portions 242 resist and deformably slide over the extending portions 145, and latch into the latching holes 122. Accordingly, the extending portions 145 latch into the cutouts 244 and are retained between the bottom of the main plate 22 and the resisting surface 246. The holding pieces 248 elastically resist against the sidewalls 12 of the frame 10.

The latching hole 122 is defined proximate to the top wall 14 of the frame, while the corresponding depression portion 242 latched into the latching hole 122 is adjacent to the main plate 22. Therefore, the height of the shield can 50 can be greatly reduced.

It is to be understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A shield can, comprising:
a frame including a top wall and sidewalls extending downwardly from the periphery of the top wall, the sidewalls defining a plurality of latching holes extending through the sidewalls and adjacent the top wall, and the top wall forming extending portions above the latching holes;
an enclosure including a main plate and walls extending downwardly from the periphery of the main plate, the wall forms depression portions corresponding in position to the latching holes, each depression portion defining a cutout extending through the main plate;
wherein when the enclosure is attached to the frame, the depression portions latch into the latching holes and the extending portions latch into the cutouts correspondingly.

2. The shield can as claimed in claim 1, wherein the depression portion protrudes from the internal surface of the wall.

3. The shield can as claimed in claim 1, wherein the depression portion defines the cutout and forms a resisting surface, the extending portions latch into the cutouts and are retained between bottom of the main plate and the resisting surface.

4. The shield can as claimed in claim 1, wherein the wall forms a plurality of holding pieces with the tail end toward the inside of the enclosure, the holding pieces resist the sidewalls of the frame after assembly the enclosure with the frame.

5. The shield can as claimed in claim 1, wherein the extending portions are wave-shaped.

6. A shield can, comprising:
a frame including a top wall and sidewalls connecting the top wall, each of the sidewalls defining a latching hole adjacent the top wall, and the top wall comprising extending portions received into the latching holes;
an enclosure attached to and covering the frame, the enclosure including a main plate and walls connecting the main plate, the wall comprising depression portions adjacent to the main plate, each of the depression portions defining a through cutout, the depression portions latching into the latching holes and the extending portions latching into the cutouts.

7. The shield can as claimed in claim 6, wherein the depression portion protrudes from the internal surface of the wall.

8. The shield can as claimed in claim 6, wherein the depression portion defines the cutout and forms a resisting surface, the extending portions latch into the cutouts and are retained between bottom of the main plate and the resisting surface.

9. The shield can as claimed in claim 6, wherein the wall forms a plurality of holding pieces with the tail end toward the inside of the enclosure, the holding pieces resist the sidewalls of the frame after assembly the enclosure with the frame.

10. The shield can as claimed in claim 6, wherein the extending portions are wave-shaped.
